(19) United States
(12) Patent Application Publication
(10) Pub. No.: US 2015/0188514 A1
(43) Pub. Date: Jul. 2, 2015

(54) RESONATOR ELEMENT, RESONATOR, OSCILLATOR, ELECTRONIC APPARATUS, SENSOR, AND MOBILE OBJECT

(71) Applicant: SEIKO EPSON CORPORATION, Tokyo (JP)

(72) Inventors: Akinori YAMADA, Ina-shi (JP); Takashi YAMAZAKI, Shiojiri-shi (JP); Shuhei YOSHIDA, Minowa-machi (JP); Toshinari JOKURA, Minowa-machi (JP)

(21) Appl. No.: 14/582,712

(22) Filed: Dec. 24, 2014

(30) Foreign Application Priority Data
Dec. 27, 2013 (JP) 2013-273625

(51) Int. Cl. H03H 9/21; G01L 1/10; H03B 5/32

(52) U.S. Cl. CPC H03H 9/21; H03B 5/32; G01L 1/106

(57) ABSTRACT

A resonator element includes: a base portion; a vibrating arm including an arm portion, extending from the base portion, and a wide portion which is connected to a distal end of the arm portion and has a width larger than that of the arm portion; a first driving electrode provided in the vibrating arm; and a weight layer which is provided in the wide portion and has a thickness larger than that of the first driving electrode. The weight layer includes a first weight portion, and a second weight portion which is disposed on the base portion side with respect to the first weight portion and has a fixed-width portion having a width smaller than that of the first weight portion.

### BACKGROUND

1. Technical Field

The present invention relates to a resonator element, a resonator, an oscillator, an electronic apparatus, a sensor, and a mobile object.

2. Related Art

Resonators (quartz crystal resonators) using quartz crystal have excellent frequency temperature characteristics, and thus are widely used as reference frequency sources, transmission sources, and the like of various electronic apparatuses and mobile objects.

Such a resonator generally includes a tuning fork type resonator element (for example, see JP-A-2011-199332 and JP-A-2012-044235).

For example, a resonator element disclosed in JP-A-2012-044235 includes a base portion and a pair of vibrating arms extending from the base portion. Each of the vibrating arms includes an arm portion, a first weight portion which is located at the distal end side with respect to the arm portion and has a width larger than that of the arm portion, and a second weight portion which is located between the arm portion and the first weight portion and has a width larger than that of the arm portion and smaller than that of the first weight portion. In the resonator element disclosed in JP-A-2012-044235, the second weight portion is provided with a weight layer constituted by a metal coating. It is possible to perform a frequency adjustment by partially removing the weight layer using a laser beam, an ion beam, or the like.

However, in the resonator element disclosed in JP-A-2012-044235, the weight layer is provided in the first weight portion of which the distal end side has a large width, and thus it is difficult to remove the weight layer with a high level of accuracy at the time of removing the weight layer using an ion beam. This is because an area to be removed of the weight layer is large or variations occur in the amount of weight layer being removed due to a difficulty in managing the position accuracy of a metal mask, which is used at the time of irradiation with the ion beam, with a high level of accuracy and due to a difficulty in managing a distance between the metal mask and the resonator element with a high level of accuracy.

That is, all of the positioning accuracy of a tray, which is used at the time of irradiation with an ion beam and has a plurality of resonators mounted thereon, and a package for the resonators when seen in a plan view, the position accuracy of the package and a resonator element in a plan view at the time of mounting the resonator element on the package, the superposition accuracy of the tray and the metal mask in a plan view, and the position accuracy of the tray and the metal mask in a plan view based on the thermal expansion of the metal mask and the tray due to changes in temperature at the time of irradiation with the ion beam are added together, and thus it is difficult to manage the position accuracy of the metal mask and the resonator element with a high level of accuracy. For this reason, a region irradiated with the ion beam extends along an extension direction of the vibrating arm and is shifted with respect to a center line of the vibrating arm which passes through the center of the length of the vibrating arm (width of the vibrating arm) in a direction perpendicular to the extension direction when seen in a plan view, and thus there is a concern that the balance of the vibration of the vibrating arm after a frequency adjustment may be lost and vibration leakage may increase.

In addition, since distortion is present in the tray and the metal mask, it is also difficult to manage a superposition distance at the time of superposing the tray and the metal mask on each other, with a high level of accuracy. For this reason, the emitted ion beam is diffracted in the vicinity of an end of an opening of the metal mask, and thus the in-plane position and the amount of processing of the ion beam reaching the resonator element become unstable. Accordingly, the amount of weight layer being removed using the ion beam varies due to the position, and thus there is a concern that the balance of the vibration of the vibrating arm after a frequency adjustment may be lost and vibration leakage may increase.

### SUMMARY

An advantage of some aspects of the invention is to provide a resonator element capable of performing a fine adjustment of a resonance frequency of a vibrating arm with a high level of accuracy and a resonator, an oscillator, an electronic apparatus, a sensor, and a mobile object which include the resonator element.

The invention can be implemented as the following application examples.

### Application Example 1

This application example of the invention is directed to a resonator element including a base portion; a vibrating arm which includes an arm portion extending from the base portion when seen in a plan view, and a wide portion which is disposed on a side opposite to the base portion side of the arm portion when seen in a plan view and has a width along a direction intersecting the extension direction which is larger than that of the arm portion; an excitation electrode which is provided in the vibrating arm; and a weight layer which is provided in the wide portion and has a thickness larger than that of the excitation electrode. The weight layer includes a first weight portion, and a second weight portion which is disposed on the base portion side with respect to the first weight portion when seen in a plan view and has a fixed-width portion having a width along the intersecting direction which is smaller than that of the first weight portion.

According to the resonator element described above, it is possible to remove a portion of the weight layer on the base end side with a high level of accuracy by removing the second weight portion. For this reason, it is possible to perform a fine adjustment of a resonance frequency of the vibrating arm with a high level of accuracy.

### Application Example 2

In the resonator element according to the application example described above, it is preferable that the wide portion includes a first wide portion provided with the first weight portion, and a second wide portion which is provided with the second weight portion and has a width along the intersecting direction which is smaller than that of the first wide portion.

With this configuration, it is possible to form the second weight portion simply and with a high level of accuracy.

### Application Example 3

In the resonator element according to the application example described above, it is preferable that the vibrating arm is provided with a groove along the extension direction and an end of the groove on a side opposite to the base portion side when seen in a plan view is located at the second wide portion.

With this configuration, a difference in rigidity between a portion of the vibrating arm in which the groove is formed and a portion thereof in which the groove is not formed can be reduced, and thus it is possible to reduce an increase in the concentration of stress generated when an impact is applied and to reduce the deterioration of impact resistance.

### Application Example 4

In the resonator element according to the application example described above, it is preferable that a relation of W2/W1≧1.2 is satisfied when a width of the arm portion along the intersecting direction is set to W1 and a width of the second wide portion along the intersecting direction is set to W2.

With this configuration, it is possible to increase the mass of the second wide portion and to achieve the stability of vibration characteristics.

### Application Example 5

In the resonator element according to the application example described above, it is preferable that a relation of W3/W2≧1.2 is satisfied when a width of the second wide portion along the intersecting direction is set to W2 and a width of the first wide portion along the intersecting direction is set to W3.

With this configuration, it is possible to increase the mass of the first wide portion and to achieve the stability of vibration characteristics.

### Application Example 6

In the resonator element according to the application example described above, it is preferable that a relation of 0.1≦H2/W2≦1.5 is satisfied when a width of the second wide portion along the intersecting direction is set to W2 and a length of the second wide portion along the extension direction is set to H2.

With this configuration, it is possible to achieve an increase in the mass and a reduction in the size of the first wide portion while achieving the stability of vibration characteristics.

### Application Example 7

In the resonator element according to the application example described above, it is preferable that the first weight portion and the second weight portion are provided on one principal surface side out of a pair of principal surfaces of the wide portion which serve as front and back sides, and the weight layer includes a third weight portion which is provided on the other principal surface side of the wide portion and which overlaps the first weight portion and the second weight portion when seen in a plan view.

With this configuration, it is possible to increase the mass of the weight layer and to increase the width of an adjustment (mainly, a coarse adjustment) of a resonance frequency of the vibrating arm.

### Application Example 8

In the resonator element according to the application example described above, it is preferable that the third weight portion is biasedly provided on the base portion side when seen in a plan view.

With this configuration, when a portion on the distal end side of the wide portion may come into contact with another structure such as a package at the time of receiving an impact or the like from the outside, it is possible to prevent the weight layer from coming into contact with the structure. For this reason, it is possible to prevent a resonance frequency of the vibrating arm from being shifted due to the weight layer being scraped by the contact.

### Application Example 9

In the resonator element according to the application example described above, it is preferable that the third weight portion is biasedly provided on a side opposite to the base portion when seen in a plan view.

With this configuration, when a portion on the base end side of the wide portion may come into contact with another structure such as a package at the time of receiving an impact or the like from the outside, it is possible to prevent the weight layer from coming into contact with the structure. For this reason, it is possible to prevent a resonance frequency of the vibrating arm from being shifted due to the weight layer being scraped by the contact.

### Application Example 10

In the resonator element according to the application example described above, it is preferable that the weight layer is formed using a deposition method.

A film formed by a sputtering method often includes unnecessary gas involved during the film formation. Such a film discharges the above-mentioned unnecessary gas by heat such as reflow and decreases the degree of vacuum within the package which is sealed at vacuum pressure. As a result, there is a problem in that the Q value is deteriorated due to an increase in air resistance at the time of bending vibration. On the other hand, in the deposition method, film formation is performed in a high vacuum state, and thus unnecessary gas is rarely involved during the film formation. For this reason, it is possible to prevent such a problem from occurring by forming the weight layer using the deposition method.

### Application Example 11

In the resonator element according to the application example described above, it is preferable that the vibrating arm is provided with a groove along the extension direction, and a distance between a distal end of a portion of the excitation electrode which is disposed within the groove when seen in a plan view and a base end of the weight layer is equal to or greater than 10 μm and equal to or less than 200 μm.

With this configuration, it is possible to prevent the excitation electrode from being short-circuited due to the weight layer while increasing the mass of the weight layer.

### Application Example 12

This application example of the invention is directed to a resonator including the resonator element according to the application example described above and a package which accommodates the resonator element.

With this configuration, it is possible to provide the resonator having excellent vibration characteristics.

### Application Example 13

This application example of the invention is directed to an oscillator including the resonator element according to the application example described above and a circuit which is electrically connected to the resonator element.

With this configuration, it is possible to provide the oscillator having excellent oscillation characteristics.

### Application Example 14

This application example of the invention is directed to an electronic apparatus including the resonator element according to the application example described above.

With this configuration, it is possible to provide the electronic apparatus having excellent reliability.

### Application Example 15

This application example of the invention is directed to a sensor including the resonator element according to the application example described above.

With this configuration, it is possible to provide the sensor having excellent detection characteristics.

### Application Example 16

This application example of the invention is directed to a mobile object including the resonator element according to the application example described above.

With this configuration, it is possible to provide the mobile object having excellent reliability.

### BRIEF DESCRIPTION OF THE DRAWINGS

The invention will be described with reference to the accompanying drawings, wherein like numbers reference like elements.

FIG. 1 is a plan view of a resonator according to a first embodiment of the invention.

FIG. 2 is a cross-sectional view taken along line A-A in FIG. 1.

FIG. 3 is a cross-sectional view (cross-sectional view taken along line B-B in FIG. 1) of a resonator element included in the resonator shown in FIG. 1.

FIG. 4 is a diagram illustrating heat conduction at the time of the bending vibration of a vibrating arm.

FIG. 5 is a graph showing a relationship between a Q value and f/fm.

FIG. 6 is a plan view of the resonator element included in the resonator shown in FIG. 1.

FIGS. 7A and 7B are partially enlarged views illustrating a wide portion and a weight layer shown in FIG. 6, and FIG. 7A is a plan view and FIG. 7B is a cross-sectional view (longitudinal sectional view) which is taken along line C-C in FIG. 7A.

FIGS. 8A and 8B are partially enlarged views illustrating a first frequency adjustment (coarse adjustment) of the resonator element shown in FIG. 1, and FIG. 8A is a plan view and FIG. 8B is a longitudinal sectional view.

FIGS. 9A and 9B are partially enlarged views illustrating a second frequency adjustment (fine adjustment) of the resonator element shown in FIG. 1, and FIG. 9A is a plan view and FIG. 9B is a longitudinal sectional view.

FIG. 10 is a longitudinal sectional view showing a wide portion and a weight layer according to a second embodiment of the invention.

FIG. 11 is a longitudinal sectional view showing a wide portion and a weight layer according to a third embodiment of the invention.

FIG. 12 is a longitudinal sectional view showing a wide portion and a weight layer according to a fourth embodiment of the invention.

FIG. 13 is a longitudinal sectional view showing a wide portion and a weight layer according to a fifth embodiment of the invention.

FIG. 14 is a longitudinal sectional view showing a wide portion and a weight layer according to a sixth embodiment of the invention.

FIG. 15A is a plan view showing a wide portion and a weight layer according to a seventh embodiment of the invention, and FIG. 15B is a plan view showing a modification example of the weight layer shown in FIG. 15A.

FIG. 16 is a cross-sectional view showing an example of an oscillator according to the invention.

FIG. 17 is a perspective view showing an electronic apparatus (notebook personal computer) which includes the resonator element according to the invention.

FIG. 18 is a perspective view showing an electronic apparatus (mobile phone) which includes the resonator element according to the invention.

FIG. 19 is a perspective view showing an electronic apparatus (digital still camera) which includes the resonator element according to the invention.

FIG. 20 is a perspective view showing a mobile object (vehicle) which includes the resonator element according to the invention.

### DESCRIPTION OF EXEMPLARY EMBODIMENTS

Hereinafter, a resonator element, a resonator, an oscillator, an electronic apparatus, a sensor, and a mobile object according to the invention will be described in detail on the basis of preferred embodiments shown in the drawings.

### 1. Resonator

### First Embodiment

First, a resonator to which a resonator element according to the invention is applied (resonator according to the invention) will be described.

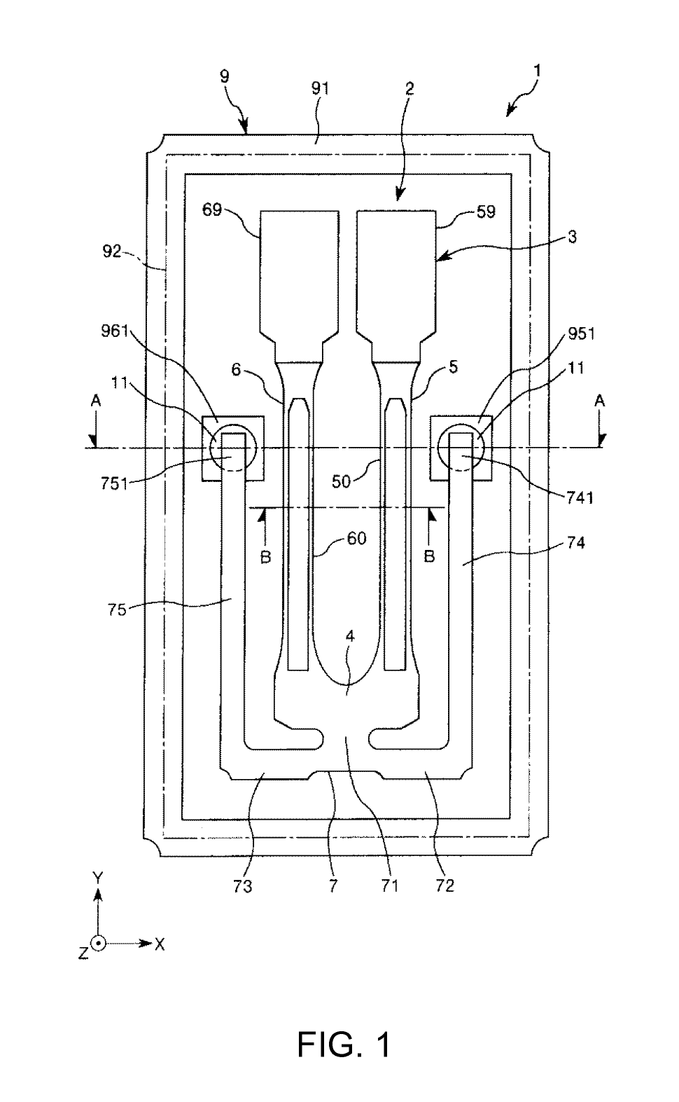

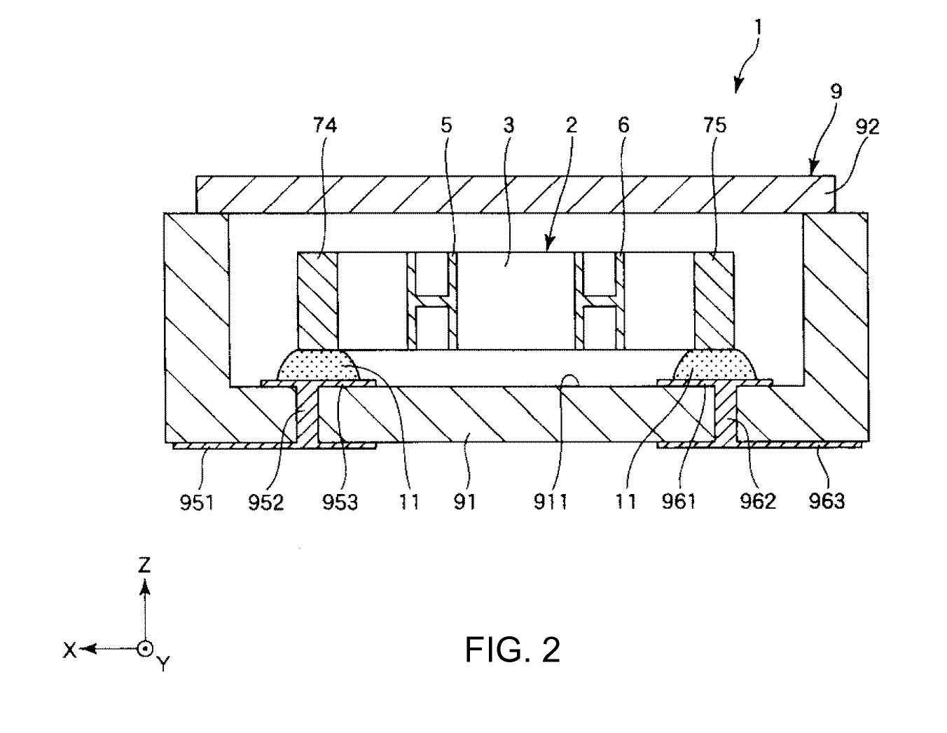

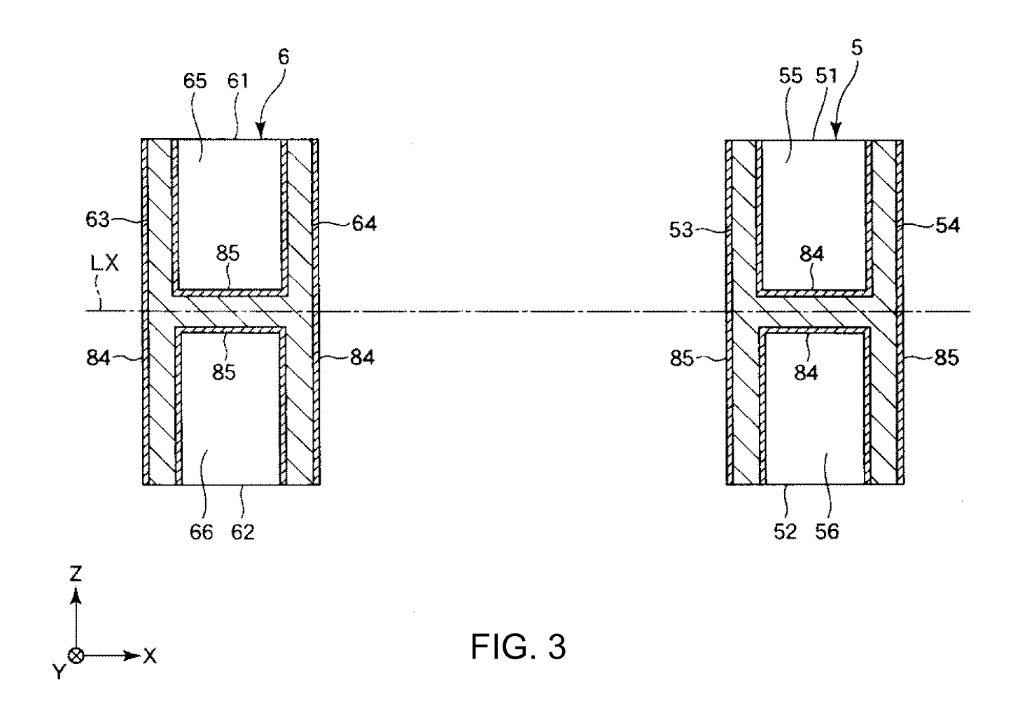

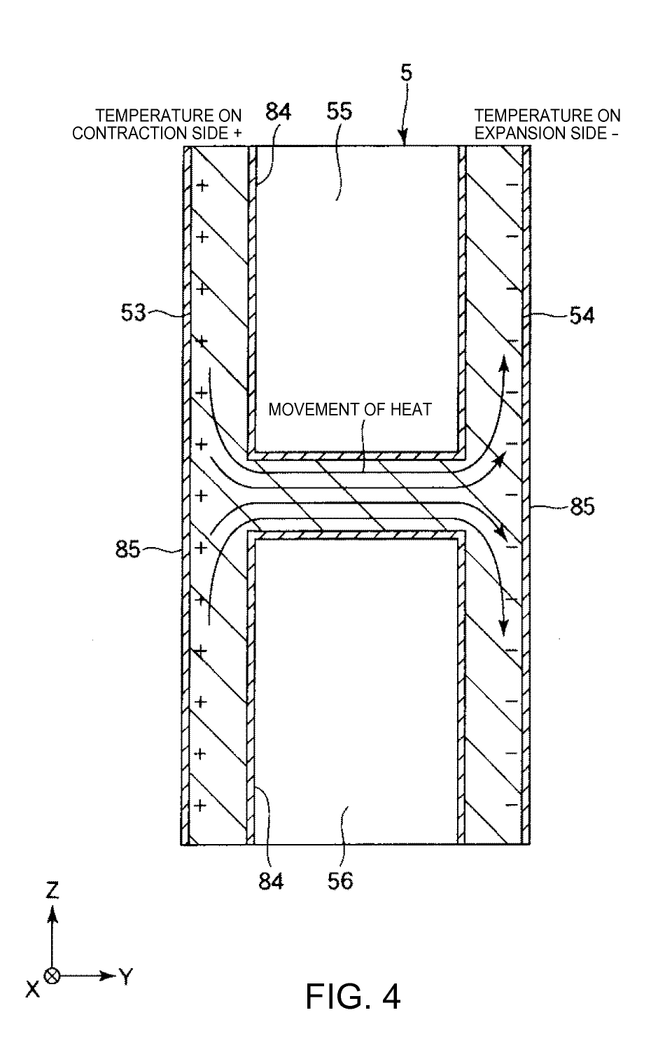

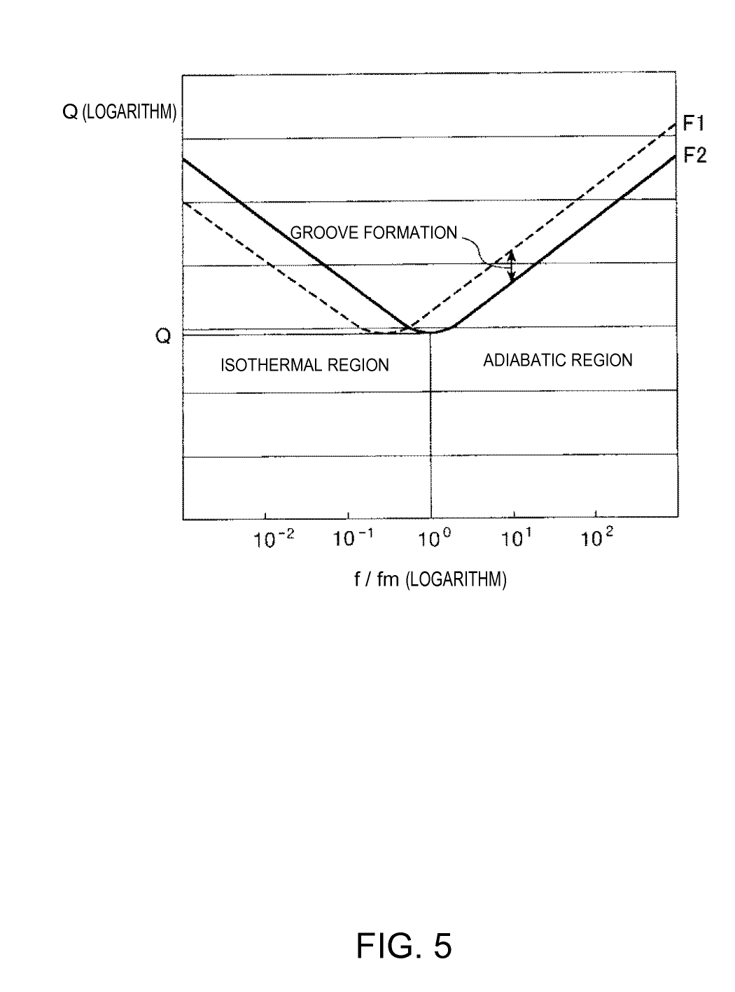

FIG. 1 is a plan view of a resonator according to a first embodiment of the invention. FIG. 2 is a cross-sectional view taken along line A-A in FIG. 1. FIG. 3 is a cross-sectional view (cross-sectional view taken along line B-B in FIG. 1) of a resonator element included in the resonator shown in FIG. 1. FIG. 4 is a diagram illustrating heat conduction at the time of the bending vibration of a vibrating arm. FIG. 5 is a graph showing a relationship between a Q value and f/fm.

Hereinafter, for convenience of description, as shown in FIG. 1, three axes orthogonal to each other are assumed to be an X-axis (electric axis), a Y-axis (mechanical axis), and a Z-axis (optical axis). In addition, a direction parallel to the X-axis (second direction) will be referred to as an “X-axis direction”, a direction parallel to the Y-axis (first direction) will be referred to as a “Y-axis direction”, and a direction parallel to the Z-axis (third direction) will be referred to as a “Z-axis direction”. In the drawings, the distal end sides of arrows showing these axe will be referred to as “+(positive)”, and the base end sides thereof will be referred to as “− (negative)”. In addition, a +Z-axis direction side will be referred to as “up”, and a −Z-axis direction side will be referred to a “down”.

A resonator 1 shown in FIGS. 1 and 2 includes a resonator element 2 (resonator element according to the invention) and a package 9 which accommodates the resonator element 2. Hereinafter, the resonator element 2 and the package 9 will be sequentially described in detail.

### Resonator Element 2

As shown in FIGS. 1, 2, and 3, the resonator element 2 according to this embodiment includes a quartz crystal substrate 3, and a first driving electrode 84 and a second driving electrode 85 (excitation electrodes) which are formed on the quartz crystal substrate 3. In FIGS. 1 and 2, for convenience of description, the first driving electrode 84 and the second driving electrode 85 are not shown.

The quartz crystal substrate 3 is constituted by a Z-cut quartz crystal plate. Thereby, the resonator element 2 can exhibit excellent vibration characteristics. The Z-cut quartz crystal plate refers to a quartz crystal substrate in which a Z-axis (optical axis) of quartz crystal is set to be a thickness direction. Meanwhile, it is preferable that the Z-axis of quartz crystal coincide with the thickness direction of the quartz crystal substrate 3, but is slightly (for example, approximately less than 15 degrees) inclined in the thickness direction from the viewpoint of reducing a frequency temperature change in the vicinity of a room temperature.

As shown in FIG. 1, the quartz crystal substrate 3 includes a base portion 4, a pair of vibrating arms 5 and 6 extending from the base portion 4, and a supporting portion 7 extending from the base portion 4.

The base portion 4 is expanded along an XY plane which is a plane parallel to the X-axis and the Y-axis and has a plate shape in which the Z-axis direction is set to be a thickness direction. In addition, the supporting portion 7 includes a connection portion 71 extending from the base portion 4 in the −Y-axis direction, connection arms 72 and 73 branching and extending from the connection portion 71 in the +X-axis direction and the −X-axis direction, respectively, and holding arms 74 and 75 respectively extending from the distal ends of the connection arms 72 and 73 in the +Y-axis direction.

The vibrating arms 5 and 6 extend from the base portion 4 in the +Y-axis direction so as to be aligned in the X-axis direction and to be parallel to each other. Each of the vibrating arms 5 and 6 has a longitudinal shape and is configured such that the base end thereof on the base portion 4 side is a fixed end and that the distal end thereof which is present in the +Y-axis direction from the base end is a free end. In addition, the distal ends of the vibrating arms 5 and 6 are respectively provided with wide portions 59 and 69 (hammerheads) of which the widths along the X-axis direction are larger than the widths of arm portions 50 and 60 on the base end side.

The wide portions 59 and 69 are provided with weight layers 57 and 67 for a frequency adjustment, respectively. Meanwhile, the weight layers 57 and 67 and the wide portions 59 and 69 will be described later.

As shown in FIG. 3, the vibrating arm 5 includes a pair of principal surfaces 51 and 52 which are constituted by an XY plane and serve as front and back sides and a pair of side surfaces 53 and 54 which are constituted by a YZ plane and connect the pair of principal surfaces 51 and 52. In addition, the vibrating arm 5 includes a bottomed groove 55 which opens to the principal surface 51 and a bottomed groove 56 which opens to the principal surface 52. The grooves 55 and 56 extend in the Y-axis direction. The vibrating arm 5 has a cross-section having a substantially H shape in a portion in which the grooves 55 and 56 are formed.

As shown in FIG. 3, it is preferable that the grooves 55 and 56 be formed symmetrically with respect to a line segment LX dividing the thickness of the vibrating arm 5 into two parts in the cross-section thereof and be formed so that the cross-sectional center of gravity of the vibrating arm 5 coincides with the center of the shape of the vibrating arm 5. Thereby, it is possible to suppress unnecessary vibration (specifically, oblique vibration and torsional vibration having an out-of-plane direction component) of the vibrating arm 5 and to efficiently vibrate the vibrating arm 5 in an in-plane direction of the quartz crystal substrate 3.

Similarly to the vibrating arm 5, the vibrating arm 6 includes a pair of principal surfaces 61 and 62 which are constituted by an XY plane and serve as front and back sides and a pair of side surfaces 63 and 64 which are constituted by a YZ plane and connect the pair of principal surfaces 61 and 62. In addition, the vibrating arm 6 includes a bottomed groove 65 which opens to the principal surface 61 and a bottomed groove 66 which opens to the principal surface 62. The grooves 65 and 66 extend in the Y-axis direction. The vibrating arm 6 has a cross-section having a substantially H shape in a portion in which the grooves 65 and 66 are formed.

The vibrating arm 5 is provided with a pair of first driving electrodes 84 and a pair of second driving electrodes 85. Specifically, one first driving electrode 84 is formed on the inner surface of the groove 55 and the other first driving electrode 84 is formed on the inner surface of the groove 56. In addition, one second driving electrode 85 is formed on the side surface 53 and the other second driving electrode 85 is formed on the side surface 54. FIG. 3 is a schematic diagram. When the grooves 55, 56, 65, and 66 are formed by wet etching, the vibrating arms have cross-sections having substantially an H shape which is different from that of FIG. 3 by the anisotropy of an etching rate, in accordance with a material of a substrate such as the quartz crystal substrate 3.

Similarly, the vibrating arm 6 is also provided with the pair of first driving electrodes 84 and the pair of second driving electrodes 85. Specifically, one first driving electrode 84 is formed on the side surface 63 and the other first driving electrode 84 is formed on the side surface 64. In addition, one second driving electrode 85 is formed on the inner surface of the groove 65 and the other second driving electrode 85 is formed on the inner surface of the groove 66.

When an AC voltage is applied between the first driving electrode 84 and the second driving electrode 85, the vibrating arms 5 and 6 vibrate at a predetermined frequency in the in-plane direction (XY plane direction) so as to repeat being close to and away from each other.

Constituent materials of the first driving electrode 84 and the second driving electrode 85 are not particularly limited, but the first and second driving electrodes can be formed of a metallic material such as gold (Au), a gold alloy, platinum (Pt), aluminum (Al), an aluminum alloy, silver (Ag), a silver alloy, chromium (Cr), a chromium alloy, copper (Cu), molybdenum (Mo), niobium (Nb), tungsten (W), iron (Fe), titanium (Ti), cobalt (Co), zinc (Zn), and zirconium (Zr), and a conductive material, such as indium tin oxide (ITO).

In this embodiment, the first driving electrode 84 and the second driving electrode 85 are configured to include two layers of a surface layer and a base layer. Meanwhile, this will be described later together with the description of the weight layers 57 and 67.

Up to now, the configuration of the resonator element 2 has been briefly described. As described above, the grooves 55, 56, 65, and 68 are formed in the vibrating arms 5 and 6 of the resonator element 2, and thus it is possible to achieve a reduction in thermoelastic loss and to exhibit excellent vibration characteristics. Hereinafter, this will be described in detail.

As described above, the vibrating arm 5 bends and vibrates in the in-plane direction by applying an AC voltage between the first driving electrode 84 and the second driving electrode 85. As shown in FIG. 4, when the vibrating arm bends and vibrates, the side surface 54 expands if the side surface 53 of the vibrating arm 5 contracts. In contrast, when the side surface 53 expands, the side surface 54 contracts. When the vibrating arm 5 does not cause a Gough-Joule effect (when energy elasticity is dominant over the entropy elasticity), the temperature on the contracted surface side of the side surfaces 53 and 54 rises, and the temperature on the expanded surface side drops. For this reason, a temperature difference occurs between the side surface 53 and the side surface 54, that is, inside the vibrating arm 5. When heat conduction occurs between the side surface 53 and the side surface 54 due to the temperature difference, loss of vibration energy occurs. Thus, the Q value of the resonator element 2 is reduced. The loss of energy will be referred to as thermoelastic loss.

In a resonator element that vibrates in a bending vibration mode and has the same configuration as that of the resonator element 2, when a bending vibration frequency (mechanical bending vibration frequency) f of the vibrating arm 5 changes, the Q value is minimized when the bending vibration frequency of the vibrating arm 5 coincides with a thermal relaxation frequency fm. The thermal relaxation frequency fm can be calculated by fm=1/(2πτ) (where, π is the circumference ratio, and relaxation time required for the temperature difference to become e⁻¹ times due to heat conduction, assuming that e is Napier's constant).

In addition, assuming that the thermal relaxation frequency of the flat plate structure is fm0, fm0 can be calculated by the following expression.

fm0=πk/(2ρCpa²) (1)

Meanwhile, π is the circumference ratio, k is the thermal conductivity in the vibration direction of the vibrating arm 5, ρ is the mass density of the vibrating arm 5, Cp is the heat capacity of the vibrating arm 5, and a is the width of the vibrating arm 5 in the vibration direction. When the constant of the material itself (that is, crystal) of the vibrating arm 5 is input to the thermal conductivity k, the mass density ρ, and the heat capacity Cp in Expression (1), the calculated thermal relaxation frequency fm0 is a value when the grooves 55 and 56 are not provided in the vibrating arm 5.

As shown in FIG. 4, in the vibrating arm 5, the grooves 55 and 56 are formed so as to be located between the side surfaces 53 and 54. For this reason, a heat transfer path for balancing the temperature by eliminating the temperature difference between the side surfaces 53 and 54, which is caused when the vibrating arm 5 bends and vibrates, by heat conduction is formed so as to bypass between the grooves 55 and 56 (bottoms of the grooves 55 and 56), and the heat transfer path becomes longer than the straight-line distance (shortest distance) between the side surfaces 53 and 54. For this reason, compared with a case where the grooves 55 and 56 are not provided in the vibrating arm 5, the relaxation time τ becomes long, and the thermal relaxation frequency fm becomes low.

FIG. 5 is a graph showing the f/fm dependence of the Q value of the resonator element in the bending vibration mode. In FIG. 5, a curve F1 indicated by the dotted line shows a case where a groove is formed in a vibrating arm as in the resonator element 2 (case where the cross-sectional shape of the vibrating arm is an H shape), and a curve F2 indicated by the solid line shows a case where no groove is formed in a vibrating arm (case where the cross-sectional shape of the vibrating arm is a rectangular shape).

As shown in FIG. 5, the shapes of the curves F1 and F2 are not changed, but the curve F1 is shifted in a frequency decrease direction with respect to the curve F2 with a reduction in the thermal relaxation frequency fm as described above. Accordingly, assuming that the thermal relaxation frequency when a groove is formed in a vibrating arm as in the resonator element 2 is fm1, the Q value of the resonator element in which a groove is formed in the vibrating arm is always higher than the Q value of the resonator element in which no groove is formed in the vibrating arm by satisfying the relation of f>√(fm0×fm1).

Further, it is possible to obtain a higher Q value when being limited to the relation of f/fm0>1.

In FIG. 5, the region of f/fm<1 is also referred to as an isothermal region. In this isothermal region, the Q value increases as f/fm decreases. This is because it is difficult for the above-mentioned temperature difference in the vibrating arm to occur as a mechanical frequency of the vibrating arm becomes low (vibration of the vibrating arm becomes slow). Accordingly, in a limit when f/fm approaches 0 infinitely, an isothermal quasi-static operation is realized, and thermoelastic loss approaches 0 infinitely. Meanwhile, the region of f/fm>1 is also referred to as an adiabatic region. In this adiabatic region, the Q value increases as f/fm increases. This is because the switching between an increase and decrease in temperature of each side surface becomes fast as the mechanical frequency of the vibrating arm becomes high, and accordingly, there is no time in which the above-mentioned heat conduction occurs. Accordingly, in a limit when f/fm is increased infinitely, an adiabatic operation is realized, and thermoelastic loss approaches 0 infinitely. From this, it can be rephrased that f/fm is in the adiabatic region if the relation of f/fm>1 is satisfied.

### Detailed Description of Weight Layer and Wide Portion

Hereinafter, the weight layers 57 and 67 and the wide portions 59 and 69 will be described in detail. Hereinafter, the weight layer 57 and the wide portion 59 will be described representatively. Since the weight layer 67 and the wide portion 69 are the same as the weight layer 57 and the wide portion 59, a description thereof will be omitted here.

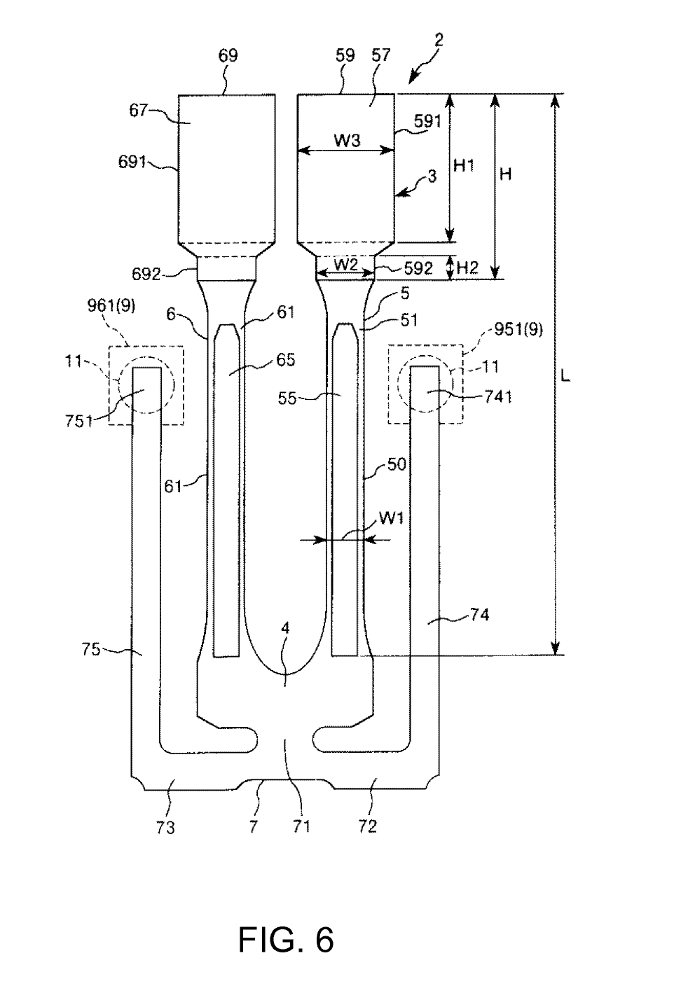

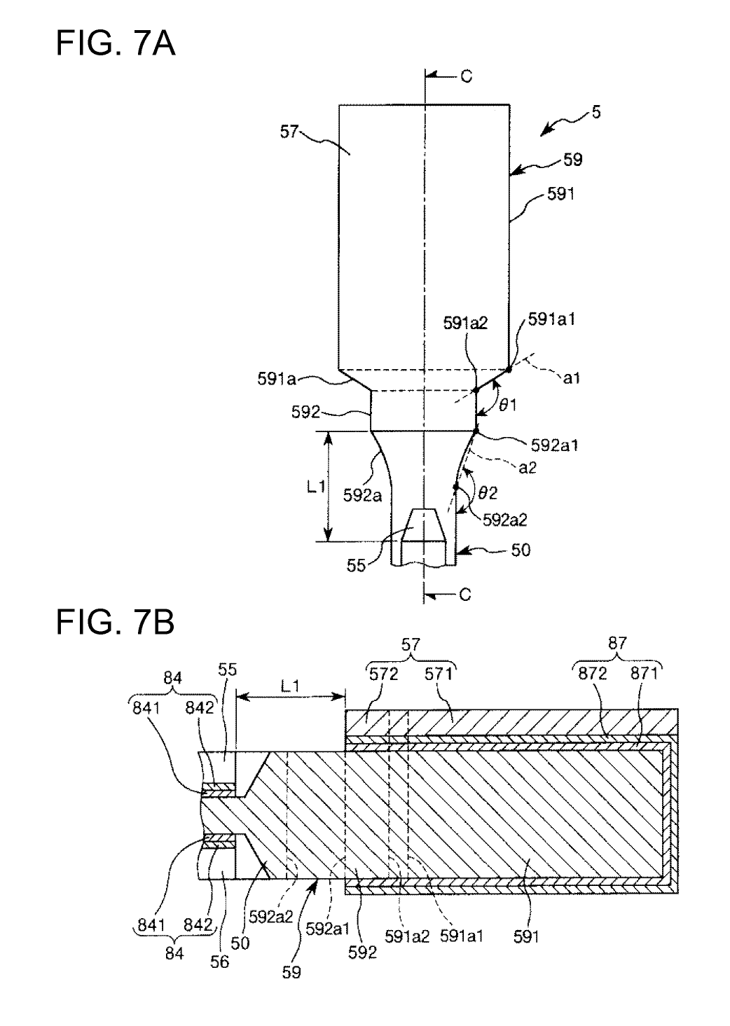

FIG. 6 is a plan view of the resonator element included in the resonator shown in FIG. 1. FIGS. 7A and 7B are partially enlarged views illustrating a wide portion and a weight layer shown in FIG. 6, and FIG. 7A is a plan view and FIG. 7B is a cross-sectional view (longitudinal sectional view) which is taken along line C-C in FIG. 7A.

As shown in FIG. 6, the vibrating arm 5 includes the arm portion 50 extending from the base portion 4, and the wide portion 59 which is connected to the distal end of the arm portion 50 and has a width larger than that of the arm portion 50.

The wide portion 59 includes a first wide portion 591 having a width larger than that of the arm portion 50, and a second wide portion 592 which is provided between the first wide portion 591 and the arm portion 50 and has a width larger than that of the arm portion 50 and smaller than that of the first wide portion 591.

An end of the first wide portion 591 on the second wide portion 592 side is provided with a tapered portion 591a of which the width becomes smaller gradually toward the second wide portion 592 side. Thus, when an impact is applied to the vibrating arm 5 from the outside due to dropping or the like, it is possible to reduce stress generated between the first wide portion 591 and the second wide portion 592. Meanwhile, a portion of the first wide portion 591 which has a constant width is provided on the distal end side with respect to the tapered portion 591a.

Similarly, an end of the second wide portion 592 on the arm portion 50 side is provided with a tapered portion 592a of which the width becomes smaller gradually toward the arm portion 50 side. Thus, when an impact is applied to the vibrating arm 5 from the outside due to dropping or the like, it is possible to reduce stress generated between the arm portion 50 and the second wide portion 592. Meanwhile, a portion of the second wide portion 592 which has a constant width is provided on the distal end side with respect to the tapered portion 592a.

It is preferable that the edges of the tapered portions 591a and 592a have shapes concavely curved to the central axis side of the vibrating arm 5, from the viewpoint of effectively reducing the above-mentioned stress.

In addition, it is preferable that taper angles θ1 and θ2 of the tapered portions 591a and 592a be equal to or greater than 140 degrees and equal to or less than 170 degrees. Thus, when the quartz crystal substrate 3 is formed by performing wet etching on a quartz crystal Z plate, it is possible to prevent a deformed portion (fin) caused by the anisotropy of quartz crystal from being formed in the tapered portions 591a and 592a. As a result, it is possible to effectively reduce the above-mentioned stress. Meanwhile, the taper angle θ1 of the tapered portion 591a is an angle formed by a line segment a1, connecting a distal end 591a1 and a base end 591a2 of the tapered portion 591a, and a line segment along an edge of the portion of the second wide portion 592 which has a constant width when seen in a plan view. In addition, the taper angle θ2 of the tapered portion 592a is an angle formed by a line segment a2, connecting a distal end 592a1 and a base end 592a2 of the tapered portion 592a, and a line segment along an edge of the portion of the arm portion 50 which has a constant width when seen in a plan view.

In addition, assuming that the width of the arm portion 50 is W1, the width of the second wide portion 592 is W2, and the width of the first wide portion 591 is W3 from the viewpoint of increasing the mass of the second wide portion 592 and achieving the stability of vibration characteristics, it is preferable that the relation of W2/W1≧1.2 be satisfied and the relation of W3/W2≧0.2 be satisfied. Meanwhile, the width W1 of the arm portion 50 is a length along the X-axis direction in the portion of the arm portion 50 which has a constant width. In addition, the width W2 of the second wide portion 592 is a width along the X-axis direction in the portion of the second wide portion 592 which has a constant width. In addition, the width W3 of the first wide portion 591 is a width along the X-axis direction in the portion of the first wide portion 591 which has a constant width.

In addition, assuming that the width of the second wide portion 592 is W2 and the length of the second wide portion 592 along the extension direction (that is, the Y-axis direction) of the arm portion 50 is H2, it is preferable that the relation of 0.1≦H2/W2≦1.5 be satisfied. Thus, it is possible to achieve an increase in the mass and a reduction in the size of the first wide portion 591 while achieving the stability of vibration characteristics.

In addition, assuming that the length (length along the Y-axis direction) of the wide portion 59 is H and the length (length along the Y-axis direction) of the vibrating arm 5 is L, it is preferable that the relation of 0.183≦H/L≦0.597 be satisfied from the viewpoint of achieving reductions in the size and thermoelastic loss of the resonator element 2 (increasing the Q value). Further it is preferable that the relation of 0.012<H/L<0.30 be satisfied from the viewpoint of decreasing a CI value.

The weight layer 57 having a thickness larger than that of the first driving electrode 84 is provided on one surface side (upper side) of the wide portion 59.

As shown in FIGS. 7A and 7B, the weight layer 57 is provided in the entirety of an upper surface of the first wide portion 591 of the wide portion 59 and a portion (the entirety of a portion having a constant width on the distal end side) of the second wide portion 592. Accordingly, the weight layer 57 includes a first weight portion 571 and a second weight portion 572 which is disposed on the base portion 4 side with respect to the first weight portion 571 and has a portion with a constant width smaller than the width of the first weight portion 571. Thus, it is possible to remove the portion of the weight layer 57 on the base portion 4 side with a high level of accuracy by removing the second weight portion 572. For this reason, it is possible to perform the fine adjustment of a resonance frequency of the vibrating arm 5 with a high level of accuracy. Meanwhile, the adjustment of the resonance frequency of the vibrating arm 5 will be described later in detail.

Here, the first weight portion 571 is provided in the first wide portion 591, and the second weight portion 572 is provided in the second wide portion 592. In other words, the wide portion 59 includes the first wide portion 591 provided with the first weight portion 571 and the second wide portion 592 which is provided with the second weight portion 572 and has a width smaller than that of the first wide portion 591. Thus, it is possible to form the second weight portion 572 simply and with a high level of accuracy. Specifically, for example, film formation is performed on the entirety of the first and second wide portions 591 and 592, it is possible to form the first weight portion 571 having a large width on the first wide portion 591 and to form the second weight portion 572 having a small width on the second wide portion 592. In this manner, it is possible to form the first weight portion 571 and the second weight portion 572, which have different widths, in accordance with the shapes of the first wide portion 591 and the second wide portion 592 simply and with a high level of accuracy, through one film forming process.

Meanwhile, in this embodiment, the first weight portion 571 and the second weight portion 572 are integrally formed, but may be separated from each other.

In addition, a constituent material of the weight layer 57 is not particularly limited, but gold is preferably used because of high specific gravity, chemical stability, and high affinity in a process of manufacturing the resonator element 2.

In addition, the thickness of the weight layer 57 may be larger than the thicknesses of the first driving electrode 84 and the second driving electrode 85. The thickness of the weight layer is not particularly limited, but is preferably two times or more and seventy times or less with respect to the thicknesses of the first driving electrode 84 and the second driving electrode 85. Thus, it is possible to reduce the adverse influence of the weight layer 57 on the vibration characteristics of the vibrating arm 5 while increasing the mass of the weight layer 57.

In addition, a method of forming the weight layer 57 is not particularly limited. However, it is preferable that a gas-phase film forming method such as a sputtering method or a deposition method be used because of the easy management of a film thickness, and it is particularly preferable that a deposition method be used. A film formed by a sputtering method often includes unnecessary gas involved during the film formation. Such a film discharges the above-mentioned unnecessary gas by heat such as reflow and decreases the degree of vacuum within the package which is sealed at vacuum pressure. As a result, there is a problem in that the Q value is deteriorated due to an increase in air resistance at the time of bending vibration. On the other hand, in the deposition method, film formation is performed in a high vacuum state, and thus unnecessary gas is rarely involved during the film formation. For this reason, it is possible to prevent such a problem from occurring by forming the weight layer 57 using the deposition method. In addition, when the weight layer 57 is formed using the deposition method, it is possible to easily form the weight layer 57 on only one surface (top face) due to a difficulty in forming the weight layer 57 on the side surface of the vibrating arm 5 and to easily remove the weight layer at the time of a frequency adjustment by using a laser or an ion beam. On the other hand, when the weight layer 57 is formed on the side surface of the vibrating arm 5, it is difficult to remove the weight layer at the time of a frequency adjustment by using a laser or an ion beam.

In this embodiment, an electrode 87 having the same layered structure as those of the first driving electrode 84 and the second driving electrode 85 is provided on the wide portion 59, and the weight layer 57 is provided on the electrode 87.

The electrode 87 is formed together with the first driving electrode 84 and the second driving electrode 85 and functions as a wiring that electrically connects portions of the second driving electrode 85. In addition, the electrode 87 also functions as a weight layer for adjusting the resonance frequency of the vibrating arm 5 together with the weight layer 57. In addition, the electrode 87 is interposed between the wide portion 59 and the weight layer 57, and thus also has a function of increasing adhesion between the weight layer 57 and the wide portion 59.

Here, the first driving electrode 84 includes a surface layer 842 and a base layer 841 which is provided between the surface layer 842 and the vibrating arm 5. Similarly, the electrode 87 also includes a surface layer 872 and abase layer 871 which is provided between the surface layer 872 and the vibrating arm 5.

Although constituent materials of the surface layers 842 and 872 are not particularly limited, for example, gold or silver is preferably used. In addition, although constituent materials of the base layers 841 and 871 are not particularly limited, for example, chromium or nickel is preferably used.

In addition, a distance L1 between a distal end of a portion of the first driving electrode 84 which is disposed within the groove 55 and a base end of the weight layer 57 is preferably equal to or larger than 10 μm and equal to or smaller than 200 μm and is more preferably equal to or larger than 10 μm and equal to or smaller than 100 μm. Thus, it is possible to prevent the first driving electrode 84 from being short-circuited due to the weight layer 57 while increasing the mass of the weight layer 57. The reason why the distance L1 is set to be in the above-mentioned range is the position accuracy of masking, which is used using a metal mask, for example, when forming the weight layer 57 by a deposition method, is approximately ±10 μm to 100 μm which is relatively large.

### Method of Adjusting Frequency

A resonance frequency of the vibrating arm 5 is adjusted in the following manner by using the weight layer 57 which is configured as described above. Hereinafter, a method of adjusting the resonance frequency of the vibrating arm 5 will be representatively described, but the same is true of a method of adjusting a resonance frequency of the vibrating arm 6. In addition, the resonance frequency of the vibrating arm 6 and the resonance frequency of the vibrating arm 5 can be simultaneously or collectively adjusted.

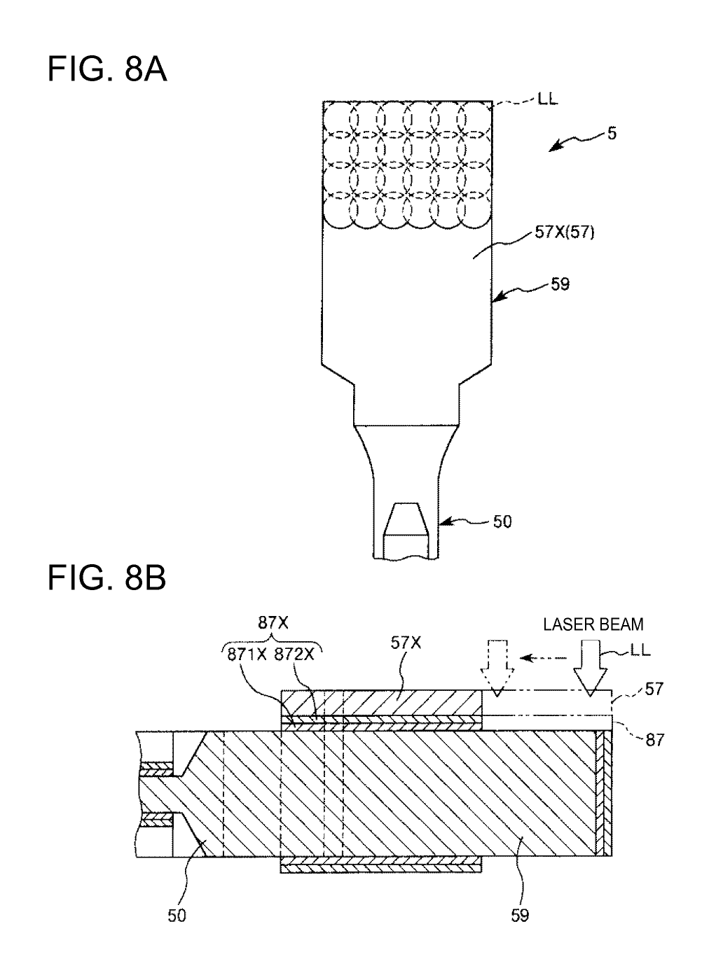

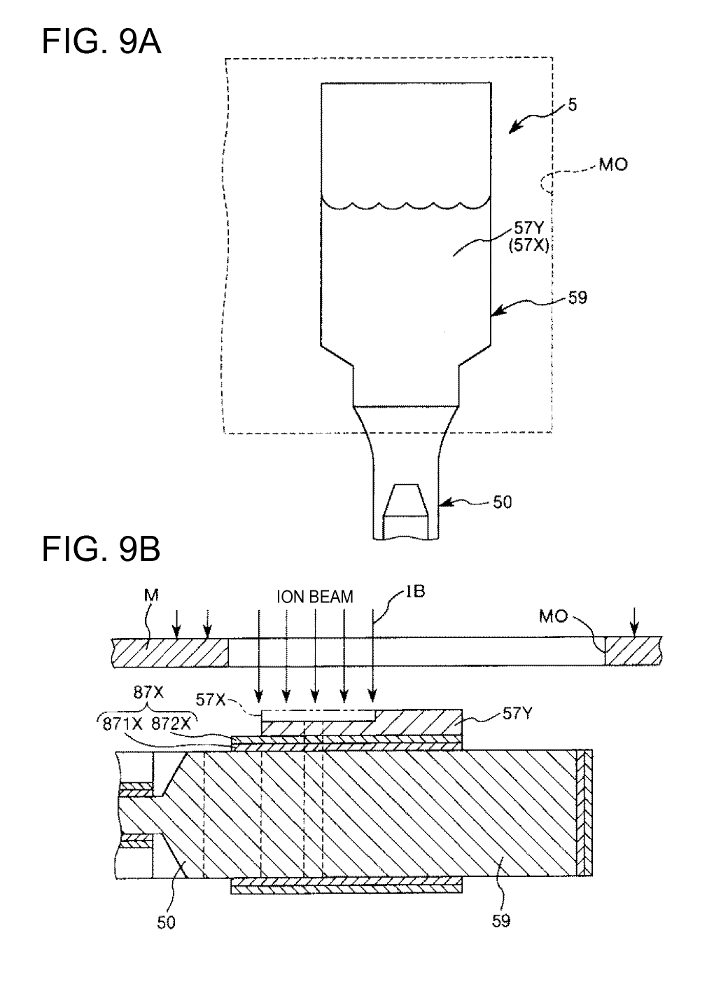

FIGS. 8A and 8B are partially enlarged views illustrating a first frequency adjustment (coarse adjustment) of the resonator element shown in FIG. 1, and FIG. 8A is a plan view and FIG. 8B is a longitudinal sectional view. In addition, FIGS. 9A and 9B are partially enlarged views illustrating a second frequency adjustment (fine adjustment) of the resonator element shown in FIG. 1, and FIG. 9A is a plan view and FIG. 9B is a longitudinal sectional view.

[1] First, the resonator element 2 before the frequency adjustment (unadjusted) is prepared.

At this time, a frequency (resonance frequency) of the vibrating arm 5 is set to be lower than a target frequency (resonance frequency). In addition, the resonator element 2 is formed by forming the external form thereof through etching of a quartz crystal wafer (quartz crystal Z plate) and then forming the first driving electrode 84, the second driving electrode 85, and the weight layers 57 and 67. At this time, the plurality of resonator elements 2 are connected to each other through a base material of the wafer. Meanwhile, the plurality of resonator elements 2 are cut into pieces, and the individual pieces of resonator elements 2 may be used. In this case, it is not necessary to cut the plurality of resonator elements 2 into pieces after a coarse adjustment to be described later.

### 2. Coarse Adjustment

First, a coarse adjustment of frequency is performed.

Specifically, as shown in FIGS. 8A and 8B, a portion (mainly, the first weight portion 571) of the weight layer 57 is removed by a required amount by irradiation with a laser beam LL. Thus, a weight layer 57X after the coarse adjustment which has reduced mass as compared with the weight layer 57 is formed. Here, the plurality of resonator elements are connected to each other through the base material of the wafer, and thus it is possible to collectively perform the first frequency adjustment (coarse adjustment) of the plurality of resonator elements 2.

FIGS. 8A and 8B show an example of a case where a portion of the first weight portion 571 of the weight layer 57 is removed. Meanwhile, the shape, region, and amount of removal of the weight layer 57 which is removed in the coarse adjustment are appropriately set when necessary, and are not limited to those shown in the drawing. For example, when a portion of the weight layer 57 is removed by irradiation with a laser beam, the removed portion of the weight layer 57 has a line shape, a dot shape, or the like.

The mass of the weight layer 57 is reduced by the coarse adjustment, and thus the weight layer changes to the weight layer 57X. Accordingly, a frequency of the vibrating arm 5 is increased. In addition, the coarse adjustment is performed so that the frequency (resonance frequency) of the vibrating arm 5 falls within a range adjustable by a fine adjustment to be described later and becomes slightly lower than a target frequency (resonance frequency). That is, the weight layer 57 is gradually removed by irradiation with the laser beam LL until the frequency (resonance frequency) of the vibrating arm 5 becomes slightly lower than a target frequency (resonance frequency). A fine adjustment to be described later is required to be performed for each resonator element 2 mounted on the resonator 1, and thus it takes time to perform the adjustment. On the other hand, a coarse adjustment performed in a state where the resonator elements are connected to each other through the base material of the wafer does not take time. For this reason, it is important to bring a frequency (resonance frequency) close to a target frequency (resonance frequency) as long as possible by a coarse adjustment. Thus, in the coarse adjustment, it is preferable that the adjustment be performed so that a frequency (resonance frequency) is set to be in a range between equal to or higher than 0.01% and equal to or lower than 10% with respect to the target frequency (resonance frequency).

In this process, a portion of the electrode 87 is also removed by the laser beam LL. In particular, the laser beam LL passes through the wide portion 59, and thus a portion of the electrode 87 on the side opposite to the weight layer 57 is also partially removed by the laser beam LL. Thus, an electrode 87X (a surface layer 872X and a base layer 871X) which is deficient in a portion of the electrode 87 is formed. Accordingly, the amount of reduced mass of the electrode 87 also contributes to the frequency adjustment.

Although a laser using the coarse adjustment is not particularly limited, lasers such as, for example, a carbon dioxide laser, an excimer laser, and a YAG laser can be used. Meanwhile, the coarse adjustment may be performed using an ion beam.

After the coarse adjustment, the plurality of resonator elements 2 are cut into pieces, and the individual pieces of resonator elements 2 are attached to a base 91 of the package 9 to be described later.

### 3. Fine Adjustment

Thereafter, a fine adjustment as a second frequency adjustment is performed.

Specifically, as shown in FIGS. 9A and 9B, a portion (mainly, the second weight portion 572) of the weight layer 57X is removed by a required amount by irradiation with an ion beam IB. Thus, a weight layer 57Y after the fine adjustment which has reduced mass as compared with the weight layer 57X is formed.

The irradiation with the ion beam IB is performed through an opening MO formed in a metal mask M. Thus, it is possible to prevent necessary portions of the first driving electrode 84 and the second driving electrode 85 from being irradiated with the ion beam IB.

Here, the position accuracy of the opening MO is not high as described above. However, since the second weight portion 572 having a small width is removed in this process, it is possible to stably irradiate a portion of the weight layer 57X which has a small area with the ion beam IB by irradiating the entirety (particularly, the entire region in the width direction) of the second weight portion 572 with the ion beam IB. For this reason, it is possible to perform the fine adjustment with a high level of accuracy.

In a portion of the weight layer 57X which is irradiated with the ion beam IB, the thickness thereof decreases in accordance with an irradiation time of the ion beam IB, and accordingly, the mass thereof becomes small.

FIGS. 9A and 9B show an example of a case where a portion of the first weight portion 571 of the weight layer 57X and the second weight portion 572 are removed. For this reason, the weight layer 57Y after the fine adjustment which is shown in the drawing has two portions having different thicknesses. Meanwhile, the shape, region, and amount of removal of the weight layer 57X which is removed in the fine adjustment are appropriately set when necessary, and are not limited to those shown in the drawing. For example, the first weight portion 571 and the second weight portion 572 of the weight layer 57X and the electrode 87X may be removed together.

The mass of the weight layer 57X is reduced by the fine adjustment, and thus the weight layer changes to the weight layer 57Y. Accordingly, the frequency of the vibrating arm 5 is increased. In addition, after the package 9 is sealed in an airtight manner, the fine adjustment is performed so that the frequency (resonance frequency) of the vibrating arm 5 coincides with a target frequency (resonance frequency) and becomes a predetermined frequency (resonance frequency). That is, the weight layer 57X is gradually removed by irradiation with the ion beam IB until the frequency (resonance frequency) of the vibrating arm 5 coincides with a target frequency (resonance frequency).

In this manner, it is possible to perform the adjustment so that the frequency of the vibrating arm 5 coincides with a target frequency.

### Package

The package 9 includes a box-shaped base 91 having a concave portion 911 which opens on the top surface, and a plate-shaped lid 92 which is bonded to the base 91 so as to close the opening of the concave portion 911. The package 9 has an accommodation space formed by closing the concave portion 911 with the lid 92, and the resonator element 2 is accommodated in the accommodation space in an airtight manner. The resonator element 2 is fixed to the bottom surface of the concave portion 911 through a conductivity adhesive 11, which is formed by mixing a conductive filler, for example, in an epoxy-based resin or an acrylic resin at the distal ends (fixation portions 741 and 751) of the holding arms 74 and 75.

Meanwhile, the inside of the accommodation space may be in a decompressed (preferably, vacuum) state, or may be filled with an inert gas such as nitrogen, helium, or argon. Thus, the vibration characteristics of the resonator element 2 are improved.

A constituent material of the base 91 is not particularly limited, but various ceramics, such as aluminum oxide, can be used. In addition, a constituent material of the lid 92 is not particularly limited, but a member having a linear expansion coefficient similar to that of the constituent material of the base 91 may be used. For example, when the above-described ceramic is used as the constituent material of the base 91, an alloy such as Kovar is preferably used. Meanwhile, bonding between the base 91 and the lid 92 is not particularly limited. For example, the base and the lid may be bonded to each other through an adhesive or may be bonded to each other by seam welding or the like.

In addition, connecting terminals 951 and 961 are formed on the bottom surface of the concave portion 911 of the base 91. Although not shown in the drawing, the first driving electrode 84 of the resonator element 2 is extracted up to the distal end (fixation portion 741) of the holding arm 74 and is electrically connected to the connecting terminal 951 through the conductivity adhesive 11 (fixation member) in the portion. Similarly, although not shown in the drawing, the second driving electrode 85 of the resonator element 2 is extracted up to the distal end (fixation portion 751) of the holding arm 75 and is electrically connected to the connecting terminal 961 through the conductivity adhesive 11 (fixation member) in the portion.

The Young's modulus of the conductivity adhesive 11 is preferably within a range between equal to or higher than 0.05 GPa and equal to or lower than 6.0 GPa and is more preferably within a range between equal to or higher than 0.05 GPa and equal to or lower than 3.0 GPa. Thus, when an impact is applied from the outside, it is possible to attenuate the impact by using the conductivity adhesive 11. As a result, it is possible to increase the impact resistance of the resonator element 2.

The conductivity adhesive 11 is not particularly limited, and it is possible to use an adhesive in which a conductive filler such as metal particles is dispersed in a resin material such as, for example, an epoxy resin or an acrylic resin.

In addition, the connecting terminal 951 is electrically connected to an external terminal 953, which is formed on the bottom surface of the base 91, through a through electrode 952 passing through the base 91. The connecting terminal 961 is electrically connected to an external terminal 963, which is formed on the bottom surface of the base 91, through a through electrode 962 passing through the base 91.

Constituent materials of the connecting terminals 951 and 961, the through electrodes 952 and 962, and the external terminals 953 and 963 are not particularly limited as long as the constituent materials have conductivity. For example, the connecting terminals, the through electrodes, and the external terminals can be constituted by a metal coating in which coatings such as nickel (Ni), gold (Au), silver (Ag), and copper (Cu) are laminated on a metallization layer (base layer) such as chromium (Cr) or tungsten (W).

The resonator 1 as described above includes the above-mentioned resonator element 2 having been subjected to a frequency adjustment with a high level of accuracy, and thus has excellent vibration characteristics. In addition, it is possible to exhibit excellent detection characteristics by using the resonator 1 as a sensor.

### Second Embodiment

Next, a second embodiment of the invention will be described.

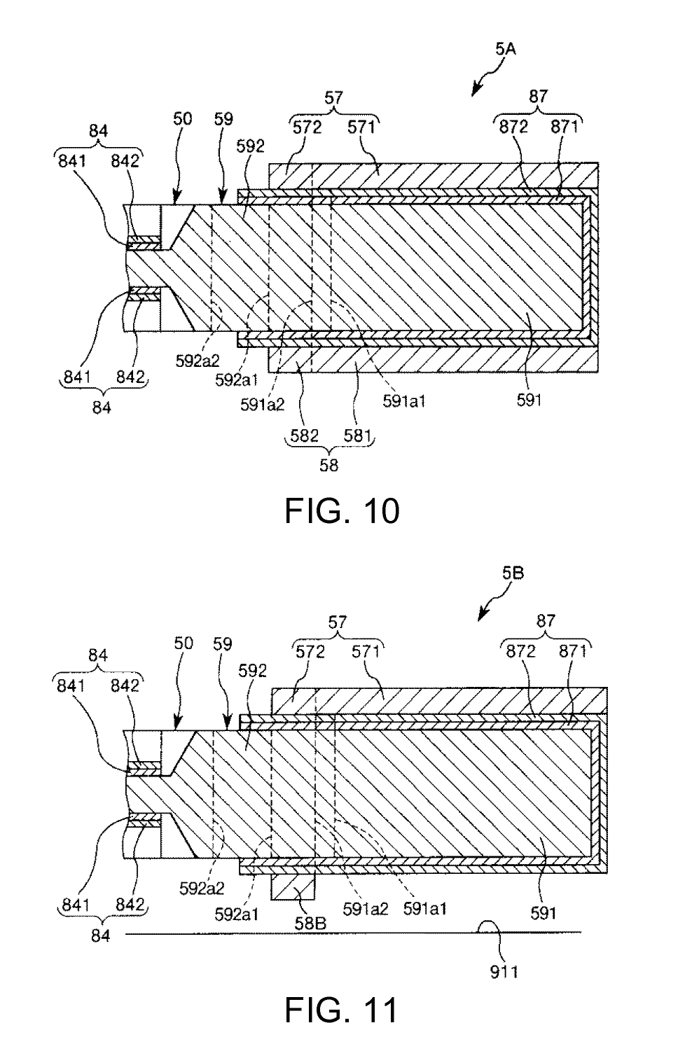

FIG. 10 is a longitudinal sectional view showing a wide portion and a weight layer according to the second embodiment of the invention.

Hereinafter, the second embodiment will be described with a focus on differences from the above-described embodiment, and a description of the same matters will be omitted.

The second embodiment is substantially the same as the first embodiment except that the configuration of a weight layer is different. In FIG. 10, the same components as those in the above-described embodiment will be denoted by the same reference numerals.

In a vibrating arm 5A shown in FIG. 10, a weight layer (third weight portion) is provided on the surface side opposite to a weight layer 57 (a first weight portion 571 and a second weight portion 572) of a wide portion 59.

The weight layer 58 faces both a first weight portion 571 and a second weight portion 572 (overlap each other when seen in a plan view) through the wide portion 59. That is, the weight layer 58 includes a weight portion 581 provided in a first wide portion 591 and a weight portion 582 provided in a second wide portion 592. Here, the weight portion 581 and the first weight portion 571 can be simultaneously removed using a laser beam during a coarse adjustment. It is possible to increase the mass of the weight layer constituted by the weight layers 57 and 58 and to increase the width of an adjustment (mainly, a coarse adjustment) of a resonance frequency of the vibrating arm 5A by providing the weight layer 58.

Also in the second embodiment described above, it is possible to perform a fine adjustment of a resonance frequency of the vibrating arm with a high level of accuracy.

### Third Embodiment

Next, a third embodiment of the invention will be described.

FIG. 11 is a longitudinal sectional view showing a wide portion and a weight layer according to the third embodiment of the invention.

Hereinafter, the third embodiment will be described with a focus on differences from the above-described embodiment, and a description of the same matters will be omitted.

The third embodiment is substantially the same as the first embodiment except that the configuration of a weight layer is different. In FIG. 11, the same components as those in the above-described embodiment will be denoted by the same reference numerals.

In a vibrating arm 5B shown in FIG. 11, a weight layer 58B (third weight portion) is provided on the surface side opposite to a weight layer 57 (a first weight portion 571 and a second weight portion 572) of a wide portion 59.

The weight layer 58B is provided biasedly on a base portion 4 side. That is, the weight layer 58B is provided biasedly in a second wide portion 592. Thus, when a portion on the distal end side of a wide portion 59 may come into contact with another structure such as a package 9 at the time of receiving an impact or the like from the outside, it is possible to prevent the weight layer 58B from coming into contact with the structure. For this reason, it is possible to prevent a resonance frequency of the vibrating arm 5B from being shifted due to the weight layer 58B being scraped by the contact.

Also in the third embodiment described above, it is possible to perform a fine adjustment of a resonance frequency of the vibrating arm with a high level of accuracy.

### Fourth Embodiment

Next, a fourth embodiment of the invention will be described.

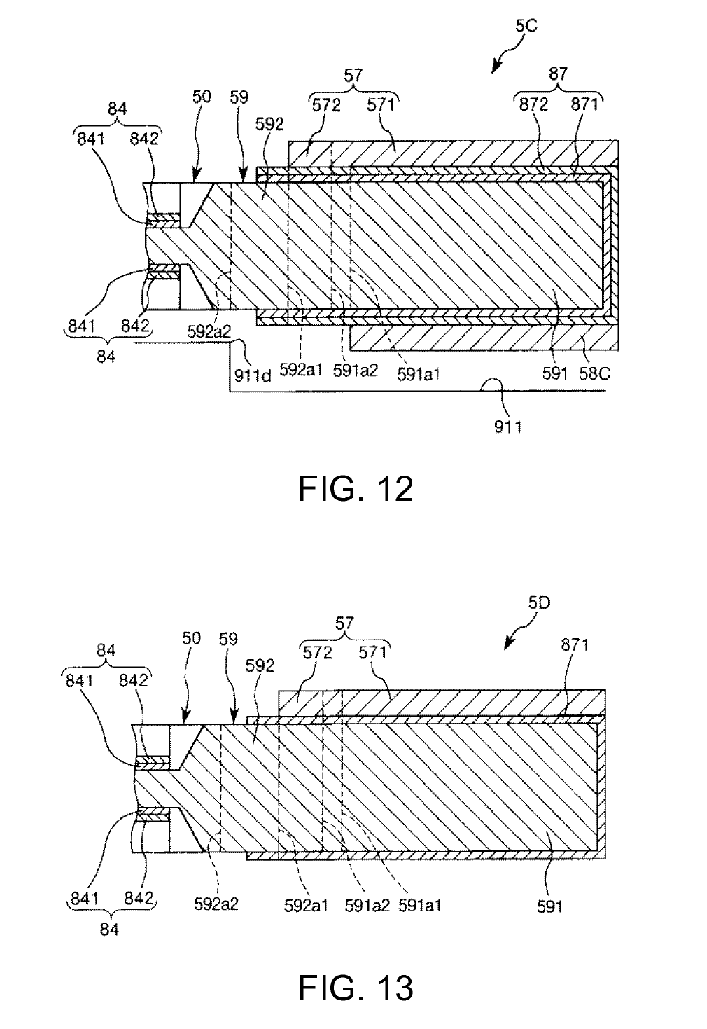

FIG. 12 is a longitudinal sectional view showing a wide portion and a weight layer according to the fourth embodiment of the invention. Hereinafter, the fourth embodiment will be described with a focus on differences from the above-described embodiment, and a description of the same matters will be omitted.

The fourth embodiment is substantially the same as the first embodiment except that the configuration of a weight layer is different. In FIG. 12, the same components as those in the above-described embodiment will be denoted by the same reference numerals.

In a vibrating arm 5C shown in FIG. 12, a weight layer 58C is provided on the surface side opposite to a weight layer 57 (a first weight portion 571 and a second weight portion 572) of a wide portion 59. That is, the weight layer 58C is provided biasedly in a first wide portion 591. Thus, when a portion on the base end side of a wide portion 59 may come into contact with another structure (for example, a corner portion 911d shown in FIG. 12) such as a package 9 at the time of receiving an impact or the like from the outside, it is possible to prevent the weight layer 58C from coming into contact with the structure. For this reason, it is possible to prevent a resonance frequency of the vibrating arm 5C from being shifted due to the weight layer 58C being scraped by the contact.

Also in the fourth embodiment described above, it is possible to perform a fine adjustment of a resonance frequency of the vibrating arm with a high level of accuracy.

### Fifth Embodiment

Next, a fifth embodiment of the invention will be described.

FIG. 13 is a longitudinal sectional view showing a wide portion and a weight layer according to the fifth embodiment of the invention.

Hereinafter, the fifth embodiment will be described with a focus on differences from the above-described embodiment, and a description of the same matters will be omitted.

The fifth embodiment is substantially the same as the first embodiment except that the configuration of an electrode between the weight layer and the wide portion is different. In FIG. 13, the same components as those in the above-described embodiment will be denoted by the same reference numerals.

A vibrating arm 5D shown in FIG. 13 is the same as the vibrating arm 5 according to the first embodiment except that the surface layer 872 of the electrode 87 is omitted. Accordingly, a weight layer 57 is provided on abase layer 871. Thus, it is possible to secure adhesion between the weight layer 57 and a wide portion 59. In addition, it is possible to reduce the above-mentioned problem caused by a film formed by a sputtering method.

Also in the fifth embodiment described above, it is possible to perform a fine adjustment of a resonance frequency of the vibrating arm with a high level of accuracy.

### Sixth Embodiment

Next, a sixth embodiment of the invention will be described.

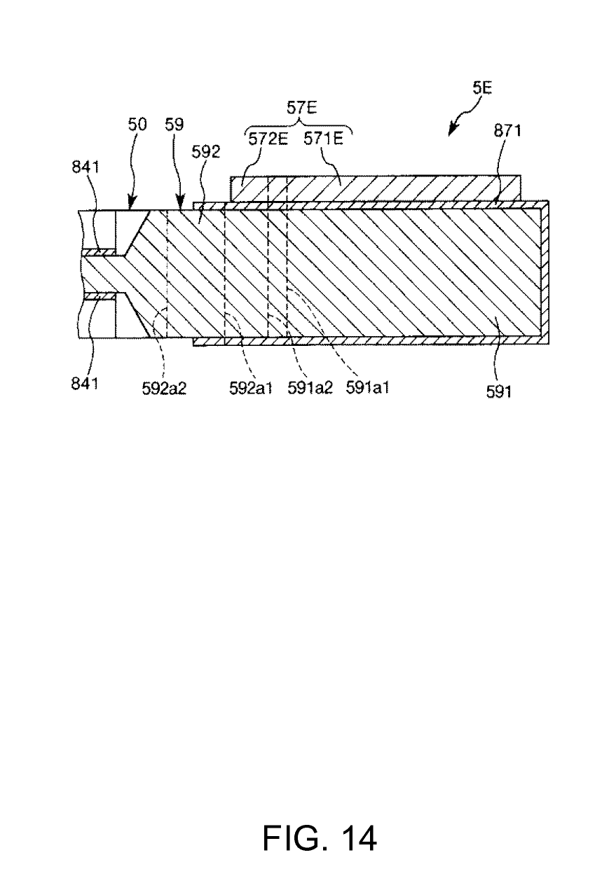

FIG. 14 is a longitudinal sectional view showing a wide portion and a weight layer according to the sixth embodiment of the invention.

Hereinafter, the sixth embodiment will be described with a focus on differences from the above-described embodiment, and a description of the same matters will be omitted.

The sixth embodiment is substantially the same as the first embodiment except that the length of a weight portion, the configuration of an electrode between the weight layer and the wide portion, and the configuration of an excitation electrode are different. In FIG. 14, the same components as those in the above-described embodiment will be denoted by the same reference numerals.

A vibrating arm 5E shown in FIG. 14 is the same as the vibrating arm 5 according to the first embodiment except that a weight layer 57E having a length shorter than that of the weight layer 57 is provided instead of the weight layer 57 and that the surface layer 842 of the first driving electrode 84 and the surface layer 872 of the electrode 87 are omitted. Accordingly, the weight layer 57E is provided on a base layer 871. Thus, it is possible to secure adhesion between the weight layer 57E and a wide portion 59. In addition, it is possible to reduce the above-mentioned problem caused by a film formed by a sputtering method.

Also in the sixth embodiment described above, it is possible to perform a fine adjustment of a resonance frequency of the vibrating arm with a high level of accuracy.

### Seventh Embodiment

Next, a seventh embodiment of the invention will be described.

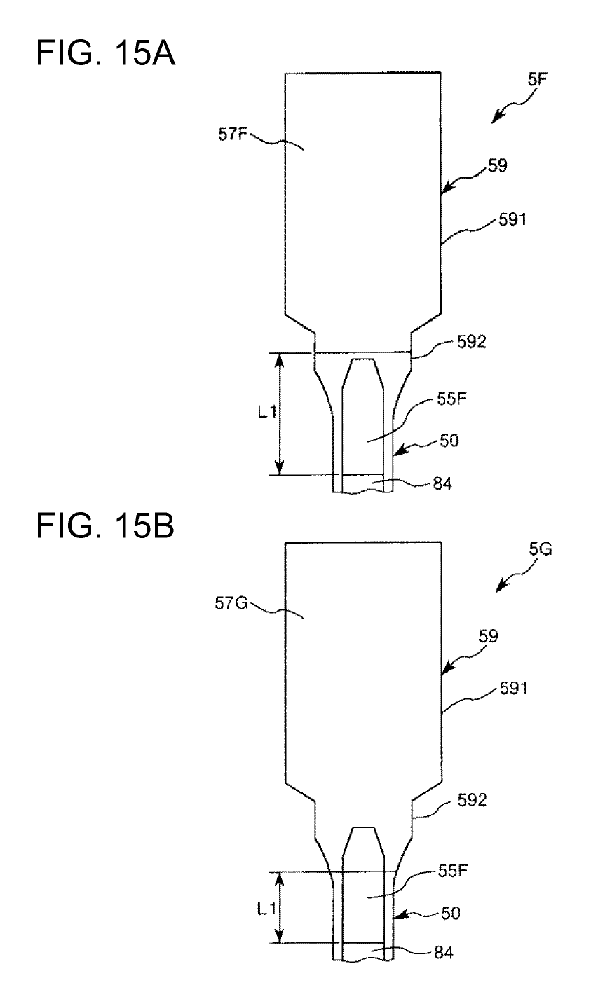

FIG. 15A is a plan view showing a wide portion and a weight layer according to a seventh embodiment of the invention, and FIG. 15B is a plan view showing a modification example of the weight layer shown in FIG. 15A.

Hereinafter, the seventh embodiment will be described with a focus on differences from the above-described embodiment, and a description of the same matters will be omitted.

The seventh embodiment is substantially the same as the first embodiment except that the length of a groove formed in a vibrating arm is different. In FIGS. 15A and 15B, the same components as those in the above-described embodiment will be denoted by the same reference numerals.

In a vibrating arm 5F shown in FIG. 15A, a groove 55F is formed along an extension direction of an arm portion 50. A distal end of the groove 55F is located at a second wide portion 592. Thereby, a difference in rigidity between a portion of the vibrating arm 5F in which the groove 55F is formed and a portion thereof in which the groove is not formed can be reduced, and thus it is possible to reduce an increase in the concentration of stress generated when an impact is applied and to reduce the deterioration of impact resistance. In addition, when the groove 55F is formed by wet etching, the groove is formed such that the depth (length in the Z-axis direction) of the groove 55F decreases gradually toward both ends (ends in the ±Y-axis direction) of the groove 55F by the anisotropy of a quartz crystal Z plate. It is possible to reduce a difference in rigidity between the portion of the vibrating arm 5F in which the groove 55F is formed and the portion thereof in which the groove is not formed, also by a region where the depth decreases gradually being located at the second wide portion 592. Further, as shown in the drawing, it is possible to reduce the difference in rigidity between the portion of the vibrating arm 5F in which the groove 55F is formed and the portion thereof in which the groove is not formed, also by a contour shape of the distal end (distal end in a direction opposite to the base end) of the groove 55F decreasing gradually toward the distal end. In the drawing, the gradual decrease is made such that the width (length in the X-axis direction) of the groove 55F changes at a constant rate, but is not particularly limited thereto. When the contour has a curved shape, it is possible to gently reduce the difference in rigidity between the portion of the vibrating arm 5F in which the groove 55F is formed and the portion thereof in which the groove is not formed, which is particularly preferable.

In addition, in the vibrating arm 5F, a weight layer 57F is provided in a wide portion 59. The base end of the weight layer 57F is located at the distal end side with respect to the distal end of the groove 55F.

In a vibrating arm 5G shown in FIG. 15B as a modification example of the vibrating arm 5F, a weight layer 57G is provided in the wide portion 59. The base end of the weight layer 57G is located at the base end side with respect to the distal end of the groove 55F.

Also in the seventh embodiment described above, it is possible to perform a fine adjustment of a resonance frequency of the vibrating arm with a high level of accuracy.

### 2. Oscillator

Subsequently, an oscillator to which the resonator element according to the invention is applied (oscillator according to the invention) will be described.

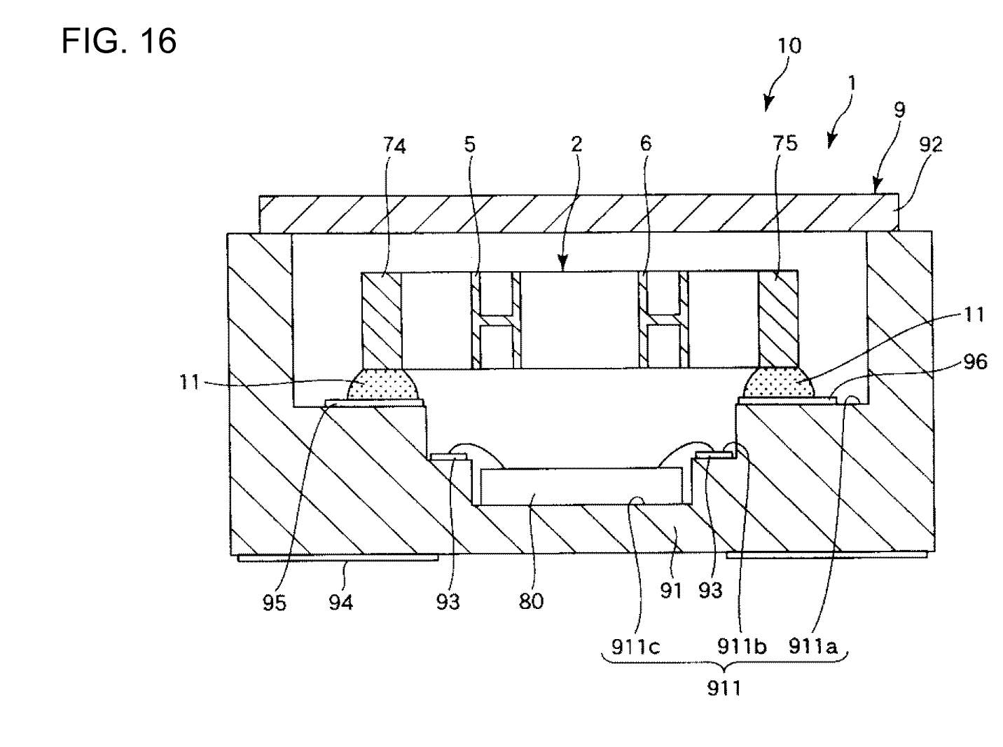

FIG. 16 is a cross-sectional view showing an example of the oscillator according to the invention.

An oscillator 10 shown in FIG. 16 includes a resonator 1 and an IC chip (chip part) 80 for driving the resonator element 2. Hereinafter, the oscillator 10 will be described focusing on the differences from the resonator described above, and a description of the same matters will be omitted here.

A package 9 includes a box-shaped base 91 having a concave portion 911 and a plate-shaped lid 92 which closes the opening of the concave portion 911.

The concave portion 911 of the base 91 includes a first concave portion 911a which opens on the top surface of the base 91, a second concave portion 911b which opens in a middle portion of the bottom surface of the first concave portion 911a, and a third concave portion 911c which opens in a middle portion of the bottom surface of the second concave portion 911b.

Connecting terminals 95 and 96 are formed on the bottom surface of the first concave portion 911a. In addition, an IC chip 80 is disposed on the bottom surface of the third concave portion 911c. The IC chip 80 includes a driving circuit (oscillation circuit) for controlling the driving of the resonator element 2. When the resonator element 2 is driven by the IC chip 80, it is possible to extract a signal of a predetermined frequency.

In addition, a plurality of internal terminals 93 electrically connected to the IC chip 80 through a wire are formed on the bottom surface of the second concave portion 911b. A terminal electrically connected to an external terminal (mounting terminal) 94 formed on the bottom surface of the package 9 through a via, not shown in the drawing, which is formed in the base 91, a terminal electrically connected to the connecting terminal 95 through a via or a wire not shown in the drawing, and a terminal electrically connected to the connecting terminal 96 through a via or a wire not shown in the drawing are included in the plurality of internal terminals 93.

In the configuration shown in FIG. 16, the IC chip is disposed within an accommodation space, but the arrangement of the IC chip 80 is not particularly limited. For example, the IC chip may be disposed outside the package 9 (disposed on the bottom surface of the base).

The oscillator 10 includes the above-mentioned resonator element 2 having been subjected to a frequency adjustment with a high level of accuracy, and thus has excellent oscillation characteristics.

### 3. Electronic Apparatus

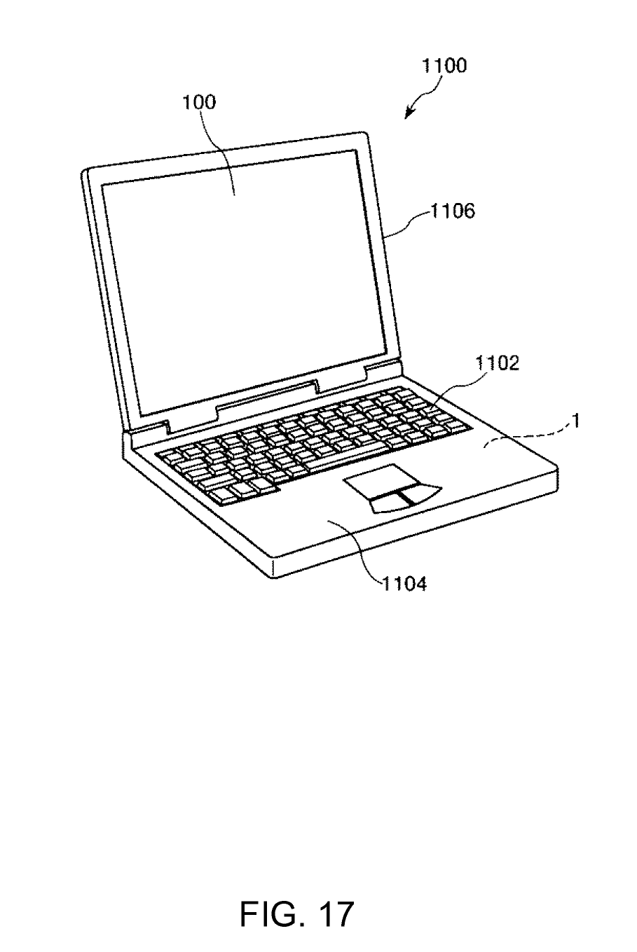

Subsequently, an electronic apparatus to which the resonator element according to the invention is applied (electronic apparatus according to the invention) will be described in detail with reference to FIGS. 17 to 19.

FIG. 17 is a perspective view showing the configuration of a mobile (or notebook) personal computer to which an electronic apparatus including the resonator element according to the invention is applied. In the drawing, a personal computer 1100 is configured to include a main body 1104 having a keyboard 1102 and a display unit 1106 having a display portion 100, and the display unit 1106 is supported so as to be rotatable with respect to the main body 1104 through a hinge structure. The resonator 1 that functions as a filter, a resonator, a reference clock, and the like is built in the personal computer 1100.

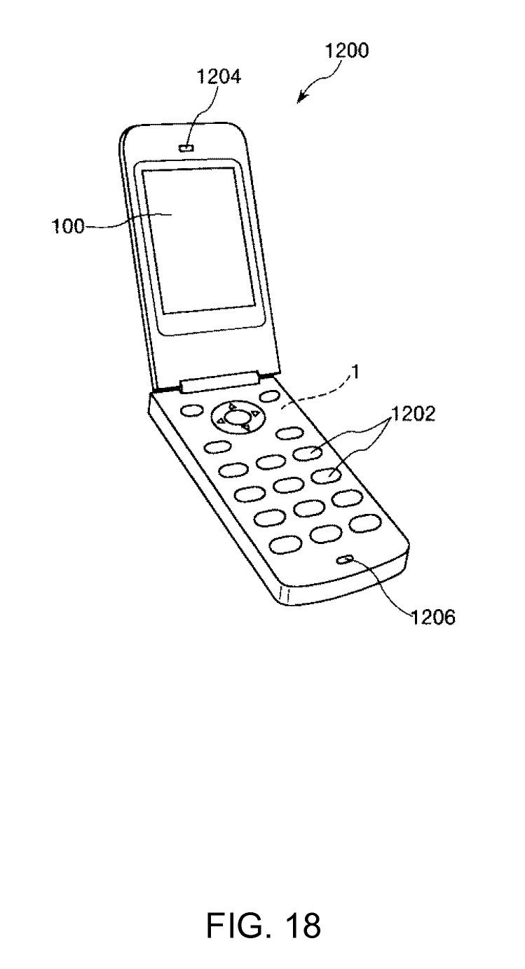

FIG. 18 is a perspective view showing the configuration of a mobile phone (PHS is also included) to which an electronic apparatus including the resonator element according to the invention is applied. In the drawing, a mobile phone 1200 includes a plurality of operation buttons 1202, an earpiece 1204, and a mouthpiece 1206, and a display portion 100 is disposed between the operation buttons 1202 and the earpiece 1204. The resonator 1 that functions as a filter, a resonator, and the like is built in the mobile phone 1200.

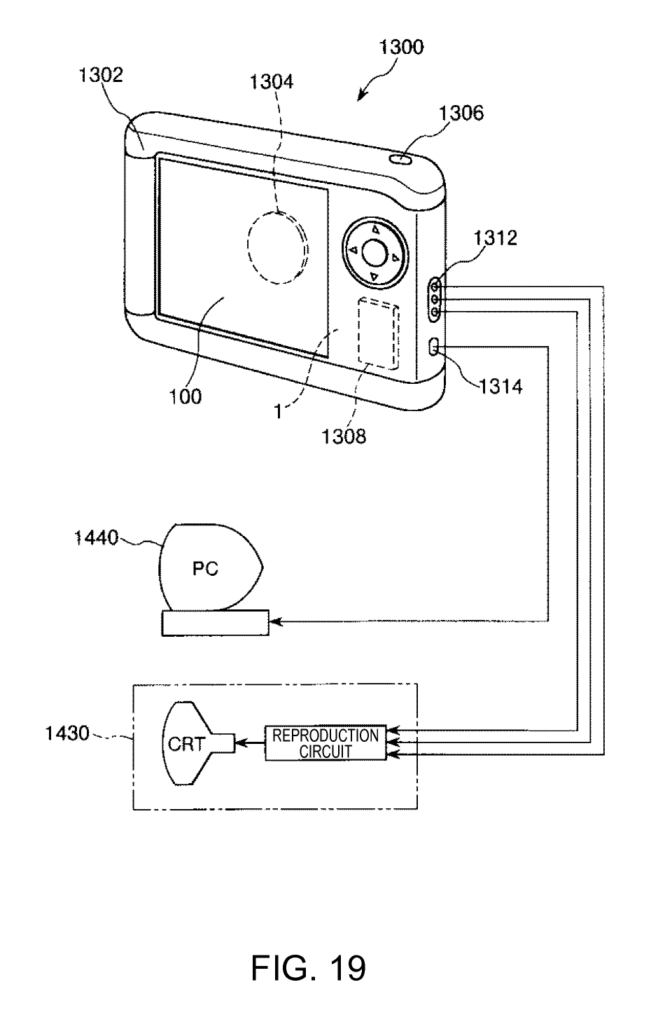

FIG. 19 is a perspective view showing the configuration of a digital still camera to which an electronic apparatus including the resonator element according to the invention is applied. In the drawing, connection with an external device is simply shown. Here, a silver halide photograph film is exposed to light according to an optical image of a subject in a typical camera, while the digital still camera 1300 generates an imaging signal (image signal) by performing photoelectric conversion of an optical image of a subject using an imaging element, such as a charge coupled device (CCD).

A display unit is provided on the back of a case (body) 1302 in the digital still camera 1300, so that display based on the imaging signal of the CCD is performed. The display unit functions as a viewfinder that displays a subject as an electronic image. In addition, a light receiving unit 1304 including an optical lens (imaging optical system), a CCD, and the like is provided on the front side (back side in the drawing) of the case 1302.

When a photographer checks a subject image displayed on the display unit and presses a shutter button 1306, an imaging signal of the CCD at that point in time is transferred and stored in a memory 1308. In addition, in the digital still camera 1300, a video signal output terminal 1312 and an input/output terminal for data communication 1314 are provided on the side surface of the case 1302. In addition, as shown in the drawing, a television monitor 1430 is connected to the video signal output terminal 1312 and a personal computer 1440 is connected to the input/output terminal for data communication 1314 when necessary. In addition, an imaging signal stored in the memory 1308 may be output to the television monitor 1430 or the personal computer 1440 by a predetermined operation. The resonator 1 that functions as a filter, a resonator, and the like is built in the digital still camera 1300.

The above-described electronic apparatus includes the above-mentioned resonator element 2 having been subjected to a frequency adjustment with a high level of accuracy, and thus has excellent reliability.

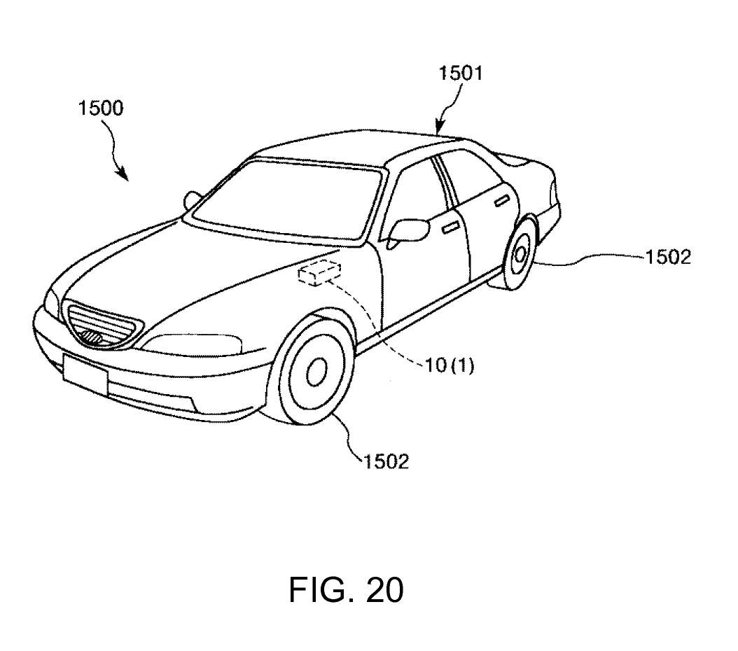

Meanwhile, the electronic apparatus including the resonator element according to the invention can be applied not only to the personal computer (mobile personal computer) shown in FIG. 17, the mobile phone shown in FIG. 18, the digital still camera shown in FIG. 19, and a mobile object of FIG. 20 but also to an ink jet type discharge apparatus (for example, an ink jet printer), a laptop type personal computer, a television, a video camera, a video tape recorder, a car navigation apparatus, a pager, an electronic organizer (an electronic organizer with a communication function is also included), an electronic dictionary, an electronic calculator, an electronic game machine, a word processor, a workstation, a video phone, a television monitor for security, electronic binoculars, a POS terminal, medical equipment (for example, an electronic thermometer, a sphygmomanometer, a blood sugar meter, an electrocardiographic measurement device, an ultrasonic diagnostic apparatus, and an electronic endoscope), a fish finder, various measurement apparatuses, instruments (for example, instruments for vehicles, aircraft, and ships), a flight simulator, and the like.

### 4. Mobile Object

FIG. 20 is a perspective view showing a mobile object (vehicle) which includes the resonator element according to the invention. In the drawing, a mobile object 1500 includes a vehicle body 1501 and four wheels 1502, and is configured so as to rotate the wheels 1502 by a power source (engine), not shown in the drawing, which is provided in the vehicle body 1501. The resonator element 2 is mounted in the mobile object 1500. The resonator element 2 can be widely applied to an electronic control unit (ECU), such as a keyless entry, an immobilizer, a car navigation system, a car air-conditioner, an anti-lock brake system (ABS), an airbag, a tire pressure monitoring system (TPMS), an engine control, a battery monitor of a hybrid vehicle or an electric vehicle, and a vehicle body position control system.

The mobile object includes the above-mentioned resonator element 2 having been subjected to a frequency adjustment with a high level of accuracy, and thus has excellent reliability.

Up to now, the resonator element, the resonator, the oscillator, the electronic apparatus, the sensor, and the mobile object according to the invention have been described on the basis of the embodiments shown in the drawings, but the invention is not limited thereto. The configuration of each portion can be replaced with any configuration having the same function. In addition, any other components may be added to the invention.

In addition, a sensor, for example, such as a gyro sensor can be applied as the resonator element.

Although this embodiment has been described as above in detail, it can be easily understood by a person skilled in the art that various modifications without substantially departing from the new matters and effects of the invention are possible. Therefore, these modifications are all included in the scope of the invention. For example, in the above-described embodiments and modification examples, although an example in which quartz crystal is used as a material for forming a resonator element has been described, but a piezoelectric material other than quartz crystal can be used. For example, an oxide substrate such as aluminum nitride (AlN) or lithium niobate (LiNbO₃), lithium tantalate (LiTaO₃), lead zirconate titanate (PZT), lithium tetraborate (Li₂B₄O₇), or langasite (La₃Ga₅SiO₁₄), a laminated piezoelectric substrate configured by laminating piezoelectric materials, such as aluminum nitride and tantalum pentoxide (Ta₂O₅), on a glass substrate, or piezoelectric ceramics can be used.

The entire disclosure of Japanese Patent Application No. 2013-273625, filed Dec. 27, 2013 is expressly incorporated by reference herein.

What is claimed is:

1. A resonator element comprising:
a base portion;
a vibrating arm which includes an arm portion extending from the base portion when seen in a plan view, and a wide portion which is disposed on a side opposite to the base portion side of the arm portion when seen in a plan view and has a width along a direction intersecting the extension direction which is larger than that of the arm portion;
an excitation electrode which is provided in the vibrating arm; and
a weight layer which is provided in the wide portion and has a thickness larger than that of the excitation electrode,
wherein the weight layer includes a first weight portion, and a second weight portion which is disposed on the base portion side with respect to the first weight portion when seen in a plan view and has a fixed-width portion having a width along the intersecting direction which is smaller than that of the first weight portion.

2. The resonator element according to claim 1, wherein the wide portion includes a first wide portion provided with the first weight portion, and a second wide portion which is provided with the second weight portion and has a width along the intersecting direction which is smaller than that of the first wide portion.

3. The resonator element according to claim 2,
wherein the vibrating arm is provided with a groove along the extension direction, and
wherein an end of the groove on a side opposite to the base portion side when seen in a plan view is located at the second wide portion.

4. The resonator element according to claim 2, wherein when a width of the arm portion along the intersecting direction is set to W1 and a width of the second wide portion along the intersecting direction is set to W2, a relation of W2/W1≧1.2 is satisfied.

5. The resonator element according to claim 2, wherein when a width of the second wide portion along the intersecting direction is set to W2 and a width of the first wide portion along the intersecting direction is set to W3, a relation of W3/W2≧1.2 is satisfied.

6. The resonator element according to claim 2, wherein when a width of the second wide portion along the intersecting direction is set to W2 and a length of the second wide portion along the extension direction is set to H2, a relation of 0.1≦H2/W2≦1.5 is satisfied.

7. The resonator element according to claim 1,
wherein the first weight portion and the second weight portion are provided on one principal surface side out of a pair of principal surfaces of the wide portion which serve as front and back sides, and
wherein the weight layer includes a third weight portion which is provided on the other principal surface side of the wide portion and which overlaps the first weight portion and the second weight portion when seen in a plan view.

8. The resonator element according to claim 7, wherein the third weight portion is biasedly provided on the base portion side when seen in a plan view.

9. The resonator element according to claim 7, wherein the third weight portion is biasedly provided on a side opposite to the base portion when seen in a plan view.

10. The resonator element according to claim 1, wherein the weight layer is formed using a deposition method.

11. The resonator element according to claim 1,
wherein the vibrating arm is provided with a groove along the extension direction, and
wherein a distance between a distal end of a portion of the excitation electrode which is disposed within the groove when seen in a plan view and a base end of the weight layer is equal to or greater than 10 μm and equal to or less than 200 μm.

12. A resonator comprising:
the resonator element according to claim 1; and
a package which accommodates the resonator element.

13. A resonator comprising:
the resonator element according to claim 2; and
a package which accommodates the resonator element.

14. An oscillator comprising:
the resonator element according to claim 1; and
a circuit which is electrically connected to the resonator element.

15. An oscillator comprising:
the resonator element according to claim 2; and
a circuit which is electrically connected to the resonator element.

16. An electronic apparatus comprising the resonator element according to claim 1.

17. An electronic apparatus comprising the resonator element according to claim 2.

18. A sensor comprising the resonator element according to claim 1.

19. A sensor comprising the resonator element according to claim 2.

20. A mobile object comprising the resonator element according to claim 1.
